(19) United States
(12) Patent Application Publication
(10) Pub. No.: US 2026/0287796 A1
(43) Pub. Date: Sep. 24, 2026

(54) SYSTEMS POWERING A DISPLAY USING ADAPTIVE AND FLEXIBLE SOLAR CELLS

(71) Applicant: Toyota Motor Engineering & Manufacturing North America, Inc., Plano, TX (US)

(72) Inventors: Songtao Wu, Ann Arbor, MI (US); Brian K. Woods, Brighton, MI (US); Debasish Banerjee, Ann Arbor, MI (US); Ryota Tomizawa, Shizuoka-ken Susono-shi (JP); Shinya Iwasaki, Mizuho City (JP)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 19/085,358

(22) Filed: Mar. 20, 2025

(51) Int. Cl. G02B 3/00; H02S 20/26; H02S 40/22; H10K 30/40

(52) U.S. Cl. CPC G02B 3/005; H02S 20/26; H02S 40/22; H10K 30/40

(57) ABSTRACT

Systems and embodiments described relate to powering a display using a flexible device having a lens directing incident light toward solar material and display areas having components that exhibit a superior appearance for the display. In one embodiment, an electronic system includes a first portion having a lens that directs incident light within a first angular range for absorption and a second angular range toward viewing material, the viewing material within certain areas forming a first image part. The electronic system also includes the first portion having absorption components coupled to the lens, the absorption components capture energy from the incident light within the first angular range and the absorption components being hidden and the first image part being visible at the second angular range. The electronic system also includes a second portion has a light source that illuminates a second image part of the viewing material using the energy.

### TECHNICAL FIELD

The subject matter described herein relates, in general, to powering a display using solar material, and, more particularly, to powering a light source on a display using adaptive and flexible solar cells that improve aesthetics for the solar material.

### BACKGROUND

Systems use solar material to capture energy for powering electronic devices. Systems also install devices having solar cells that store energy for future usage such as power outages. For example, these systems have the solar cells packaged in solar panels installed in a metallic casing and encapsulated, such as with glass. The solar cells have photovoltaic material that releases electrons and generates an electric charge when exposed to photons from sunlight. The electric charge accumulates rapidly even with sparse photonic energy when having solar panels that are expansive. The electric charge can form current to power electronics (e.g., consumer electronics), home lighting, and small appliances. In one approach, the electric charge generates a direct current (DC) captured by circuitry in the solar panels for directly powering devices. The DC can also be converted to alternating current (AC) by an inverter for wall sockets in a building. The output power can be directly correlated with the quantity and expansiveness of solar panels. As such, panel size and quantity impact the loads and device capacities the systems can power.

Moreover, in one embodiment, systems integrating a sizable array of solar panels for powering an electronic device encounter difficulties due to poor appearances and form factors. For instance, consumers dislike the looks of having dark solar cells embedded within a case of a laptop computer. Similarly, neighborhood associations prohibit solar panels for powering lightpoles due to bulky hardware having unsightly designs. Accordingly, systems having solar panels for powering demanding loads may generate insufficient energy from aesthetic qualities that limit installing sizable arrays.

### SUMMARY

In one embodiment, example systems relate to powering a display using a flexible device having a lens directing incident light toward solar material and display areas having components that exhibit a superior appearance for the display. In one approach, systems using solar panels for powering electronic devices and displays generate insufficient energy from poor aesthetics and rigidity (e.g., flatness) that constrain array sizes during a product design. Systems that alter the appearance of a solar panel can improve aesthetics and allow increased sizes. For example, certain systems include graphics with solar panels for aesthetic purposes. However, these systems may reduce harvesting efficiency for energy by overly obstructing and interfering with sunlight. Also, displaying visuals on solar panels can be blurred and lack definition, thereby reducing the aesthetic benefits. Additionally, a solar panel integrated within a display and other electronic devices can exhibit rigid and inflexible properties, thereby limiting applications to flatter forms.

Therefore, in an example, an electronic system includes a flexible lens and photovoltaics for capturing solar energy that powers a light source and improves aesthetics and design capabilities through displaying angle-dependent imagery. Here, the electronic system can have a section that selectively directs incident light for energy capture using absorption components and otherwise towards viewing material for display. In one example, an image formed with the viewing material includes reflective components near the viewing material for improving clarity and vividness through preventing unintended energy capture. As such, the lens may transmit incident light to the viewing material and the reflective components at other angles, thereby hiding the absorption components while the viewing material is visible for allowing expansive solar capture areas and beneficial aesthetics. The section for the viewing material and energy capture can exhibit an alternating pattern that improves image quality and energy capture. Furthermore, the electronic system can power the light source that illuminates an additional section of the viewing material using captured energy such that the section and the additional section form a continuous and completed appearance. Accordingly, the electronic system powers a light source including multiple sections while improving aesthetic integration and maintaining a superior retention of energy harvesting.

In one embodiment, an electronic system powering a display using a flexible device having a lens directing incident light toward solar material and display areas having components that exhibit a superior appearance for the display is disclosed. In one embodiment, the electronic system includes a first portion having a lens that directs incident light within a first angular range for absorption and a second angular range toward viewing material, the viewing material within areas of the lens and forms a first image part. The electronic system also includes the first portion having absorption components coupled to the lens, the absorption components capture energy from the incident light within the first angular range and the absorption components being hidden and the first image part being visible at the second angular range. The electronic system also includes a second portion having a light source that illuminates a second image part of the viewing material using the energy, and the first image part and the second image part form a completed appearance.

In one embodiment, an electronic system powering a display using a flexible device having a lens directing incident light toward solar material and display areas having components that exhibit a superior appearance for the display is disclosed. In one embodiment, the electronic system includes a first portion having a lens that directs incident light within a first angular range for absorption and a second angular range toward viewing material, the viewing material within areas of the lens and forms a first image part. The electronic system also includes the first portion having absorption components coupled to the lens, the absorption components capture energy from the incident light within the first angular range and the absorption components being hidden and the first image part being visible at the second angular range. The electronic system also includes a second portion has a light source that illuminates a second image part of the viewing material using the energy, and the first image part and the second image part form a completed appearance.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIGS. 1A-1D illustrate embodiments of an electronic system exhibiting flexible properties including a lens that controls angles of light towards absorption components that absorb energy and power a light source and areas having viewing material for displaying an image.

FIGS. 2A and 2B illustrate examples of the electronic system forming various shapes and powering a light source that illuminates a display having multiple images using solar energy.

FIGS. 3A-3C illustrate embodiments and examples of the electronic system powering a display using angle-dependent imagery having integrated solar material.

### DETAILED DESCRIPTION

Systems, methods, and other embodiments associated with powering a display using a flexible device having a lens directing incident light toward solar material and display areas having components that exhibit a superior appearance for the display are disclosed herein. In various implementations, electronic systems capturing energy have silicon material using amorphous silicon exhibiting limited flexibility. This expands installation options unlike crystalline silicon that is rigid. However, flexible solar material can exhibit decreased efficiency and durability from bending compared to silicon panels that are rigid. Furthermore, electronic systems using backlighting and light sources for displays have operational constraints when relying on battery power. Powering light sources with energy captured by solar material encounters difficulties with the aforementioned inflexibility and poor aesthetic qualities when installed on buildings and other structures. Therefore, electronic systems powering components using solar material that harvests energy can be hindered by flexibility and design properties.

Therefore, in one embodiment, an electronic system has a flexible lens with flexible photovoltaics (PV) for powering a light source and transitions from transparent to displaying viewing material having an image at different angular ranges. This allows custom form factors for purpose-built applications (e.g., advertisements, lightboxes, etc.) that have enhanced design without sacrificing energy capture and efficiency. Here, the angular ranges can be viewing angles for the electronic system such that at certain directions incident light is transmitted to absorption components for capturing energy. At other directions, the incident light travels to viewing material within areas of the flexible lens that forms the image (e.g., an advertisement, a graphic, etc.) for display while hiding the absorption components, thereby improving system appearance.

In one approach, reflective components near the viewing material direct the incident light towards the viewing material for increasing clarity and vividness by hindering transmission to the absorption film. In another approach, the electronic system includes ink material directly printed onto the flexible lens that captures energy from incident light. For instance, the ink material and the viewing material form an alternating, juxtaposed, etc., pattern. In this way, the flexible lens directs the incident light within an angular range for absorption by the ink material and otherwise towards the viewing material for displaying an image that improves overall system aesthetics while powering the light source.

Moreover, in another embodiment, the electronic system has a section where the flexible PV harvests power for supplying a lightbox in another section. The flexible PV can display viewing material including imagery at a certain angular range that makes the PV unviewable while capturing energy at another angular range. The lightbox can include an image that seamlessly integrates, complements, contrasts, etc., the viewing material. In another example, the flexible PV and lightbox assembly is enclosed by a flexible lenticular cover outputting a three-dimensional (3D) depth impression. For example, a lenticular lens on the another section displays a visual effect for the image. Here, the lenticular lens can cause an image transition and motion laterally through directing incident light to certain areas of the viewing material. Accordingly, the electronic system displays clear and vivid images at certain views without obstructing solar capture at other views that improves appearance for energy capture and powers a light source, thereby expanding system installation locations and form factor capabilities.

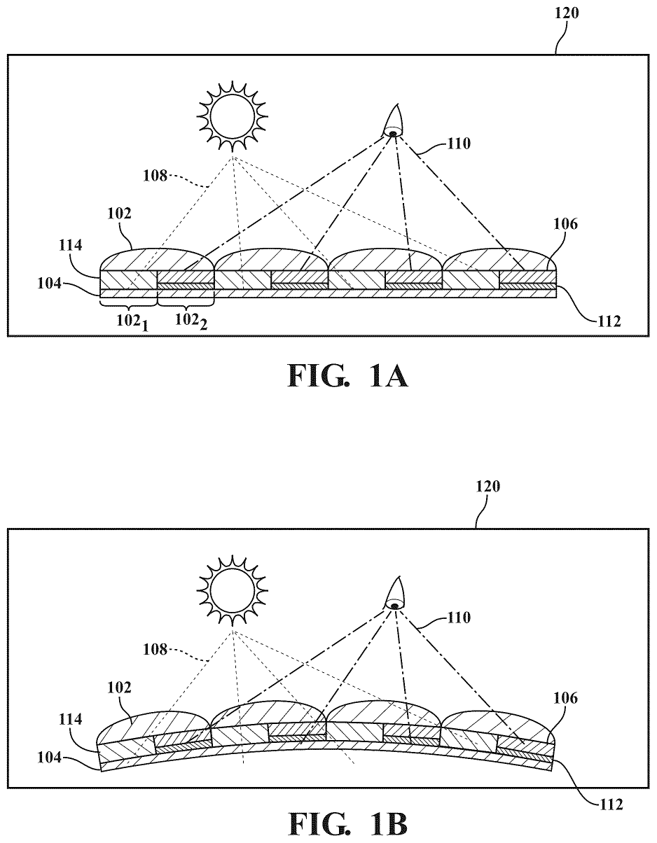

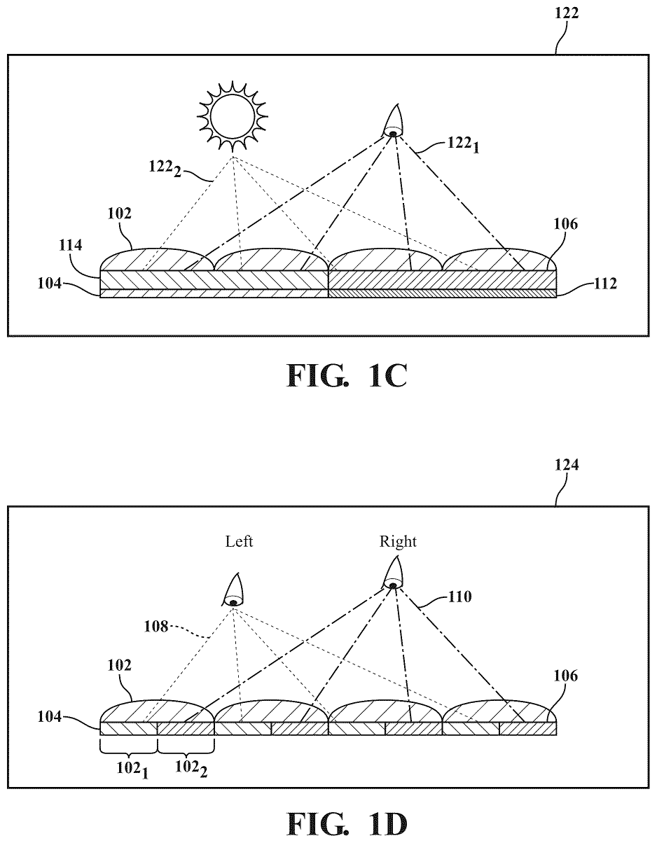

Turning to the illustrations, the systems illustrated in FIGS. 1-3 include various elements. It will be understood that in various embodiments, the systems may have less than the elements shown in FIGS. 1-3. The systems can have any combination of the various elements shown in FIGS. 1-3. Furthermore, the systems can have additional elements to those shown in FIGS. 1-3. In some arrangements, the systems may be implemented without one or more of the elements shown in FIGS. 1-3. While the various elements are shown as being located within the systems in FIGS. 1-3, it will be understood that one or more of these elements can be located external to the systems. Furthermore, the elements shown may be physically separated by large distances.

Now discussing FIGS. 1A-1D, embodiments of an electronic system exhibiting flexible properties including a lens 102 that controls angles of light towards absorption components 104 that powers a light source and areas having viewing material 106 for displaying an image are illustrated. For example, the lens 102 is a lenticular film composed with one of a polymer, polystyrene (PS), a polyethylene terephthalate (PET), and a polyethylene terephthalate glycol (PET-G) material that forms a waveguide. A lenticular film can have transparent and flexible properties and the absorption components 104 can adapt to a structural shape, thereby expanding the capabilities and applications of the electronic system. Furthermore, the absorption components 104 can be solar film that is one of copper indium gallium diselenide (CIGS) PV film and a perovskite-based PV film that exhibit certain properties for energy harvesting. Solar film has flexible properties that allow having a substrate for the lens 102.

The electronic system can include one of assembly 120, assembly 122, and assembly 124. In the forthcoming examples, the assembly 120, the assembly 122, and the assembly 124 may be references collectively as assemblies. An assembly may be installed on a building façade, a vehicle, a billboard, etc. In the forthcoming examples, angular ranges, bands, etc., may be referenced as image bands that define angles at which the image (e.g., a black and white image, a color image, etc.) is viewable by a person, machine, etc. For example, the viewing material 106 mimics an object design, communicates a message, advertises information, etc. Accordingly, the electronic system improves the aesthetics of the absorption components 104 by displaying images at certain viewing angles and at other angles being clear to directly guide solar rays toward the absorption components 104 for energy harvesting.

In one approach, the assembly 120 is associated with a first portion having the lens 102 that directs incident light within a first angular range 108 for absorption by the absorption components 104 and a second angular range 110 toward the viewing material 106. Here, the viewing material 106 are located within subunit 102₂ and the viewing material 106 can form a first image part. The absorption components 104 are coupled to the lens 102 and capture energy from the incident light within the first angular range 108. An arrangement can include the viewing material 106 being one of alternating and juxtaposed with transparent material 114 and the absorption components 104 allowing angle-dependent energy capture and image display from light exposure. In other words, the absorption components 104 are hidden and the first image part is visible at the second angular range 110, thereby improving the aesthetics and looks of the assembly 120 from certain viewing directions.

As explained below, the electronic system may include one of the assemblies along with a second portion having a light source that illuminates a second image part of the viewing material 106 using absorbed energy such that the first image part and the second image part form a completed appearance. As another example, the light source can also illuminate the first image part and the first portion and the second portion form a display associated with a lightbox. This configuration can also involve covering the first portion and the second portion by a clear acrylic forming a shell that protects the assembly 120, the assembly 122, and the assembly 124. The shell can protect against one of moisture, dust, debris, etc., without effecting energy capture and image clarity.

The assembly 120 can include reflective components 112 near the viewing material 106 within the subunit 102₂. For example, the reflective components 112 are one of opaque, semi-transparent, etc., and direct the incident light within the second angular range 110 towards the viewing material 106 that enhances image luminosity. Applying the viewing material 106 and the reflective components 112 can involve a printer directly printing to the lens 102 that improves image clarity and vividness. As given in more detail below, the absorption components 104 can be solar ink directly printed to the lens 102.

In various implementations, the viewing material 106 has a first width and transparent material 114 near the viewing material 106 has a second width. In the examples given herein, the transparent material 114 can transmit incident light to the absorption components 104 for energy capture with minimal loss, thereby improving efficiency. For instance, the first width and the second width comprises one of a 1:1 ratio, a 2:1 ratio, a 3:1 ratio, and a 1:3 ratio. This can allow different imagery and visuals formed with the viewing material 106 and energy capture levels with the absorption components 104. In another approach, the absorption components 104 are ethylene vinyl acetate (EVA) film that is transparent. For instance, the EVA film is one of CIGS PV film and a perovskite-based PV film. The EVA film can have layers that are individually encapsulated. Certain ones of the assemblies can be formed by bonding the EVA film to the reflective components 112 near the viewing material 106 and the transparent material 114 near the viewing material 106 and the reflective components 112 using an adhesive.

In FIG. 1A, the assembly 120 can include the lens 102 being a film that directs incident light within a first angular range 108 for absorption and a second angular range 110 toward the viewing material 106. In particular, the viewing material 106 and the second angular range 110 can represent image bands within one of areas, sections, etc., of the lens 102 and form an image. Here, the image can be one of a color, grayscale, black and white, etc., image. Furthermore, the reflective components 112 near the viewing material 106 within the areas of the lens 102 can direct the incident light within the second angular range 110 towards the viewing material 106. In one approach, the absorption components 104 are an absorption film bonded to the reflective components 112. In this way, the absorption film captures energy from the incident light within the first angular range 108 while hidden at the second angular range 110 from sight with the image being visible.

The lens 102 may be a waveguide that optically controls and transmits incident light transparently toward the viewing material 106 and the absorption components 104. In one approach, the lens 102 is a lenticular layer, a lenticular film, a lenticular lens, etc., composed of PET that is fully flexible, transparent, and forms a waveguide that efficiently and clearly directs incident light towards the viewing material 106 and the absorption components 104. In another approach, the lens 102 is one of a polymer, acrylic, PET, PET-G, and polystyrene material. As such, the lenticular film and the absorption film can be thin films that adapt with a structural shape unlike crystalline silicon. Regarding controlling and directing incident light, the lens 102 through customizable design has certain angular ranges (e.g., bands) of the incident light directed through a transparent path to the absorption components 104. Although FIG. 1A references film material, any composition that absorbs solar or electromagnetic energy may be integrated with the lens 102 for displaying an image while capturing energy using angle-dependence.

In various implementations, the viewing material 106 and the reflective components 112 are applied to the lens 102. For instance, these materials are applied by printing using a specialized printer that is high-resolution and precisely positions ink pigment, thereby improving image clarity by reducing ghosting and distortion. In particular, the reflective components 112 can reduce the incident light being inadvertently absorbed or transmitted to the absorption components 104. Furthermore, the absorption components 104 can be a solar film that is CIGS PV film bonded to the reflective components 112 and the transparent material 114 associated with the lens 102. Here, bonding can involve using an adhesive that is clear. For instance, an optical adhesive that is clear enhances transparency and mitigates absorption losses for energy. In this approach, manufacturing certain ones of the assemblies avoids alignment difficulties during bonding between the lens 102 and the absorption components 104 since the viewing material 106 and the reflective components 112 are directly applied to the lens 102 rather than another substrate initially. This also improves efficiency through avoiding an intermediate process.

As illustrated below, the viewing material 106 can form pixels for the image using ink that is cured through thermal, light, etc., treatment. For example, the pixels form an image viewable within certain angular ranges and transparent otherwise. In other words, the pixels are reflective since the image is viewable within the certain angular ranges. Regarding materials, the viewing material 106 may be one of ink, organic ink, pigment, organic pigment, etc., having optimal properties for improving visibility and clarity from a distance.

Regarding further details about reflectivity, in another example, the reflective components 112 direct and control unreflected light when the viewing material 106 has transparent characteristics and insufficient opaqueness from brighter colors. Furthermore, the reflective components 112 can prevent image distortions by confining light within the areas. The incident light can also reflect off the viewing material 106 without unintentional scattering, thereby providing increased reflectivity and image vividness. For instance, the reflective components 112 insulate the incident light from the absorption components 104 exhibiting darkness (e.g., black, deep blue, etc.) causing optical interference. In other words, an image formed by the viewing material 106 can be distorted by light absorbed from a color of the absorption components 104 that otherwise would irradiate the image. Therefore, a material with increased reflectivity redirects more incident light and reduces absorption by the absorption components 104, thereby reducing image distortion, improving image quality, and increasing image resolution.

Moreover, horizontally, the reflective components 112 can occupy the space per area without extruding and bleeding into the lens 102. As such, the assemblies increase harvesting efficiency and reduce blurred images through physical properties having horizontal precision. In another embodiment, the width of the reflective components 112 is congruent with the viewing material 106 through a controlled printing process that improves image contrast and sharpness.

Vertically, the reflective components 112 can occupy the space per area at a ratio with the viewing material 106 that improves thinness for the assemblies. For instance, the assembly 120 exhibits deeper colors upon the ratio having the viewing material 106 equal to or greater than the reflective components 112. The ratio may also vary by each area for forming the image and exhibiting different visual effects. Similar to horizontal features, certain configurations of the assemblies may maintain precision and reduce costs through printing within a limited number of passes (e.g., two, four, etc.). This can continue until satisfying parameters for opaqueness between the viewing material 106 and the absorption components 104. For example, the parameter is that up to 99% of the incident light reflects for irradiance rather than being absorbed by the absorption components 104. Accordingly, certain configurations of the assemblies improve reflectivity while avoiding ghosting from optical distortion and interference.

As previously described, the lens 102 can be a lenticular waveguide that controls and directs the transmission of the incident light. The lenticular waveguide can be an array of lenses that allows the visibility of the viewing material 106 at certain angles and generates optical effects. For example, the lenticular waveguide gives an image depth at certain colors and wavelengths. In one approach, the lens 102 is a lenticular waveguide having pixels and the reflective components 112 directly printed onto the lenticular waveguide. This reduces thickness by forgoing a substrate for the viewing material 106 and the reflective components 112 and bonding to the lens 102. This also avoids alignment tasks between the lens 102 and the absorption components 104 during production and manufacturing.

Certain configurations of the assemblies can increase performance by reflecting incident light to the viewing material 106 while retaining the majority of the incident light, thereby improving aesthetics and energy capture. For example, the electronic system generates above 90% reflectivity within a certain angular range from including the reflective components 112 rather than 10% reflectivity. For energy harvesting, incident light that is exposed to the absorption components reach above 90% retention instead of 80% through other implementations. Therefore, certain configurations of the assemblies display an image with the viewing material 106 that makes the absorption components 104 aesthetically pleasing and flexible increasing applications and available installation areas, thereby increasing energy capture.

FIG. 1B illustrates that the assembly 120 can have a curved form and flexibility. Here, the absorption components 104 can be fully flexible and form a substrate for the lens 102. For example, CIGS PV film can include solar cells that are fully flexible unlike silicon material (e.g., monocrystalline, polycrystalline, etc.) and exhibit efficient properties. Both the lens 102 and the CIGS PV film being fully flexible allows applications on structures having increased curvature. For example, the lens 102 and the absorption components 104 (e.g., solar film) fully curve to form a complete circle, a circular shape (e.g., 270-360 degrees), a polygon, etc. Furthermore, the CIGS PV may have multi-layers that encapsulate solar cells for durability and water resistance while maintaining full flexibility. As such, PV film allows efficient energy capture and coverage in expansive and disparate areas for powering demanding loads through increased capture areas.

As previously explained, the absorption components 104 can be an absorption film composed of EVA film that is one of transparent, semi-transparent, etc. In one approach, the EVA film is a CIGS PV film having layers that are individually encapsulated. This can increase the durability for the assemblies without impacting flexibility. Similar to other examples, the EVA film can be bonded to the reflective components 112 and transparent material 114 near the reflective components 112 using an adhesive.

In yet another example, the absorption components 104 are perovskite-based PV film that is bonded to the lens 102 and functions as a substrate that is flexible. The lens 102 can have the viewing material 106 and the reflective components 112 applied to the lens 102, such as through printing. Perovskite-based PV film is soft and flexible like CIGS PV film that can be bonded using a clear adhesive, such as an optical adhesive that is clear for enhancing transparency and mitigating energy absorption losses. In certain implementations, perovskite-based PV film can exhibit increased efficiency over CIGS PV film. Both the lens 102 (e.g., a lenticular film) and the perovskite-based PV film layer can be fully flexible. The fully flexible nature of PV film benefits applications for advertising, displays, etc., and printing the viewing material 106 and reflective components 112 on the lens 102 allows efficiency for energy harvesting and physical flexibility over other implementations (e.g., crystalline silicon).

In another approach, the transparent material 114 is one of adjacent, near, proximate, etc., to the viewing material 106 outside of certain areas associated with the lens 102. This allows the viewing material 106 and the reflective components 112 being juxtaposed, alternating, etc., with the transparent material 114. In various implementations, the transparent material 114 and the first angular range 108 represent a transparent band for transmission and energy capture associated with incident light. For instance, the lens 102 is composed of waveguide units shaped as one of a hemisphere, a demilune, a triangle, etc. The lens 102 can be uniformly designed with various lens per inch in different areas through extrusion and rolling during manufacturing. The design can also have shapes to have various curvatures for adapting with different installations and application demands. Furthermore, the areas can be subunits 102₁ and 102₂. The subunits 102₁ can represent an area having parts of the transparent material 114. The subunits 102₂ have the viewing material 106 and the reflective components 112 applied to the areas, such through printing.

As previously explained, the widths of the viewing material 106 and the reflective components 112, the transparent material 114, the subunits 102₁ and 102₂ can vary depending upon demand for energy capture and visual quality. For instance, the viewing material 106 has a first width X and the transparent material 114 near the viewing material 106 has a second width Y. As an example, the first width X and the second width Y comprise one of a 1:1 ratio, a 2:1 ratio, a 3:1 ratio, and a 1:3 ratio. A person of ordinary skill in the art understands that systems herein can also implement any ratio. As such, the electronic system can be designed where increasing X increases resolution while increasing Y increases energy capture.

The layering in FIGS. 1A-1D are illustrations. The transparent material 114 may be on a similar layer with the viewing material 106 and the reflective components 112. For instance, the viewing material 106 and the reflective components 112 have a negligible thickness when applied to the lens 102 such that the viewing material 106 and the reflective components 112 form a consistent thickness and flat surface when bonding with the absorption components 104. Furthermore, in one approach, the reflective components 112 are a bright color (e.g., white) and improve clarity and vividness for the viewing material 106 by blocking the absorption components 104 from absorbing incident light. Furthermore, the reflective components 112 increase reflectivity at the second angular range 110 for displaying colorful images and giving an attractive appearance. Vividness is also improved by reducing ghosting through shielding the incident light reflected off the absorption components 104.

In another implementation, the lens 102 is a waveguide that directs the incident light within a first band for absorption by a film layer forming the absorption components 104 and a second band toward the viewing material 106. Here, the viewing material 106 is within subunits 102₂ of the lens 102 and the viewing material 106 forms an image. The reflective components 112 can be reflective material next to the viewing material 106 within the subunits 102₂ of the lens 102. For instance, the reflective components 112 directs the incident light within the second angular range 110 towards the viewing material 106. Furthermore, the film layer can be an absorption film bonded to the reflective material and the absorption film captures energy from the incident light within the first band. This allows the absorption film to be hidden at the second band while the image is visible.

Concerning FIG. 1C, in one embodiment, the assembly 122 is a flexible PV that harvests energy and supplies power to a lightbox. As explained below, in one example, a control system draws the energy and a power system stores the energy and feeds a backlight within the lightbox. Here, a first portion having the lens 102 directs incident light within a first angular band 122₁ toward the viewing material 106. Similar to other examples, the reflective components 112 can be near the viewing material 106 for increasing clarity and vividness by hindering transmission to the absorption components 104. A second portion having the absorption components 104 coupled to the lens 102, the absorption components 104 capture energy from the incident light within the second angular band 122₂. The second portion can have a light source that illuminates the viewing material 106 using the energy. In this way, the absorption components 104 are hidden and the viewing material 106 is visible, viewable, etc., at the first angular band 122₁.

Regarding FIG. 1D, the assembly 124 can include the viewing material 106 having a first width and the absorption components 104 near the viewing material 106 having a second width. Here, the viewing material 106 may have one semi-transparent reflective components 112 or lack the reflective components 112. This allows a backlight to illuminate the viewing material 106 partially from inside the assembly 124 when lacking a reflective layer. In another approach, one of the assemblies 122 or 124 can include a diffusion layer that is uniform to ensure that the viewing material 106 is balanced, evenly illuminated, and prevent internal illumination creating hot spots. As further explained below, a purpose-built configuration for the lens 102 allows the assembly 124 and other assemblies to display a visual effect for the viewing material 106. For instance, the lens 102 causes the viewing material 106 to transition laterally between left-right by directing incident light.

In various implementations, FIG. 1D has the absorption components 104 applied on the lens 102 for capturing energy from the incident light within the first angular range 108. Otherwise, the absorption components 104 are hidden from sight and the viewing material 106 is visible by a viewer (e.g., a pedestrian). Here, the absorption components 104 can be hidden at the second angular range 110 and located outside the subunits 102₂ within the subunits 102₁. The assembly 124 having the absorption components 104 limited to the subunit 102₁ rather than the length of the lens 102 saves and reduces material costs. In this regard, a printer can print the absorption components 104 as ink to half of a bottom, side, etc., surface of the lens 102.

In another embodiment, the widths of the viewing material 106, the absorption components 104, and the subunits 102₁ and 102₂ vary depending upon demand for energy capture and visual quality. In one implementation, the viewing material 106 has a first width X and solar ink forming the absorption components 104 has a second width Y. As an example, the first width X and the second width Y comprise one of a 1:1 ratio, a 2:1 ratio, a 3:1 ratio, and a 1:3 ratio. A person of ordinary skill in the art understands that systems herein can also implement any ratio. As such, the electronic system can be designed and adaptable where increasing X increases information content while increasing Y increases energy capture.

In one approach, the absorption components 104 are ink that form solar cells when assembled in an array. For instance, the ink is perovskite-based that may be ultraviolet curable upon application to the lens 102 and fully flexible. This allows increased compatibility of the ink with various application approaches and avoids demands for a substrate. As such, a printer can apply the absorption components 104 to the lens 102 directly without a substrate. Printing also increases the flexibility of the assembly 124, thereby improving applications.

In various implementations, the assembly 124 has layers exhibiting various configurations. For instance, the lens 102 is a first layer and the viewing material 106 and the absorption components 104 form a second layer. Here, the second layer can be printed onto the first layer following alignments with the lens defined by the subunits 102₁ and 102₂. This configuration can reduce costs through utilizing regular printers and avoiding secondary manufacturing tasks. These configurations can also exhibit thinness through purpose-built printers that apply fine material and pigments. In this way, the assembly 124 has configurations that meet various application requirements and parameters.

An embodiment of the assembly 124 includes solar ink that comprises flakes made from absorption film and the solar ink and the viewing material 106 form an alternating, juxtaposed, etc., pattern. Like other embodiments, the viewing material 106 and the absorption components 104 can be directly printed to the lens 102. This increases form flexibility through utilizing inks and film materials.

The assembly 124 may include the lens 102 being a lenticular film (e.g., a polymer, acrylic, PET, PET-G, PS, etc.) forming a waveguide that is durable and moisture resistant. Here, the lenticular film, the viewing material 106, and the absorption components 104 can be a device that adapts to a structural shape. For example, the lenticular film is transparent and fully flexible. In this way, the assembly 124 allows for installations demanding adaptive form factors.

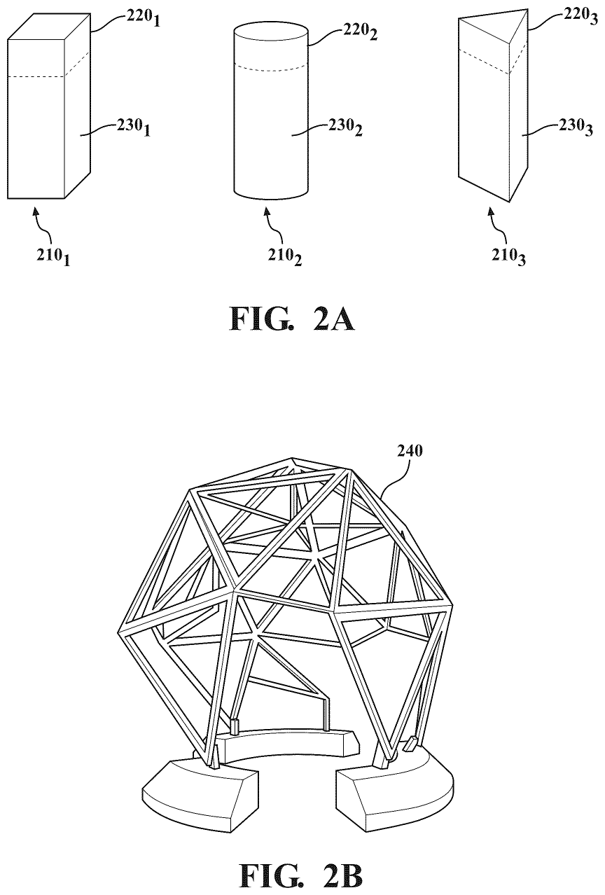

Turning to FIGS. 2A and 2B, examples of the electronic system forming varies shapes and powering a light source that illuminates a display having multiple images using solar energy are illustrated. In FIG. 2A, structures 210₁-210₃ include top portions 220₁-220₃ covered and wrapped with an assembly having an angle-dependent lens that is flexible. The structures 210₁-210₃ can exhibit one of rectangular, circular, quadrangular, tubular, cubical, etc., shapes. In FIG. 2B, the structure 240 is hexagonal with tubular components that are wrapped using the assemblies. Here, the structure 240 displays viewing material at certain angles to an observer while efficiently capturing solar energy at other angles using the assemblies. Still, one of ordinary skill in the art understands that the structures 210₁-210₃ and 240 can be formed into any shape.

In FIGS. 2A and 2B, the assembly includes absorption components that absorb solar energy at certain angles for power harvesting and projects a first image part to the viewing audience/public at other angles. These configurations include systems utilizing one of battery storage for illumination and battery storage and utility power for illumination. For instance, the top portions 220₁-220₃ include any one of the assembly 120, the assembly 122, and the assembly 124. Furthermore, bottom portions 230₁-230₃ have a light source that illuminates a second image part of viewing material using the energy. Besides horizontal configurations, another configuration can be a vertical surface in FIG. 2A having a face for harvesting using a portion from one of assemblies 120, 122, and 124. Meanwhile, another face illuminates the viewing material. In one approach, the first image part and the second image part form a completed appearance, thereby improving overall looks while capturing solar energy associated with the electronic system.

In another implementation, the assemblies wrapping a body of the top portions 220₁-220₃ have the lens 102 that is one of a lens film and a lenticular lens. For instance, the lens 102 is a rigid material that is cut, welded, and fastened as sheets at X degrees (e.g., 45 degrees) without joint and exposed fasteners. In this way, the electronic system displays an image at certain viewing angles without obstructing solar rays at other angles that improves aesthetics for solar devices and expands applications through one of full and partial flexibility.

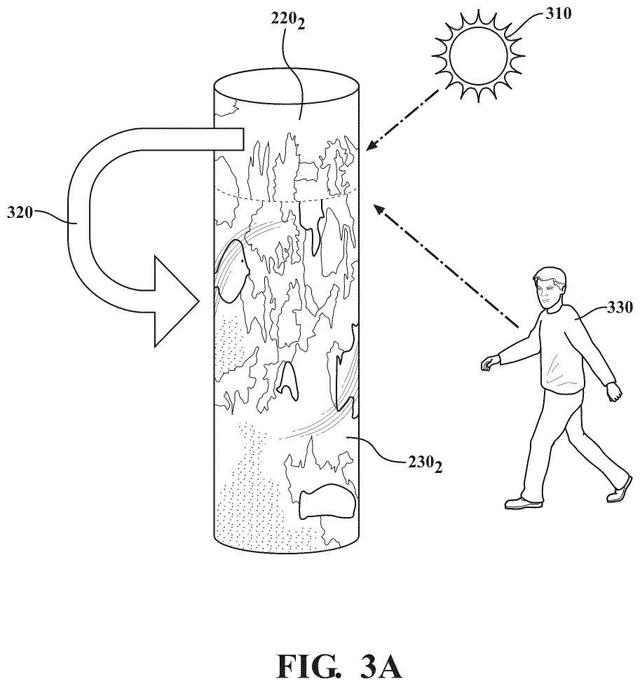

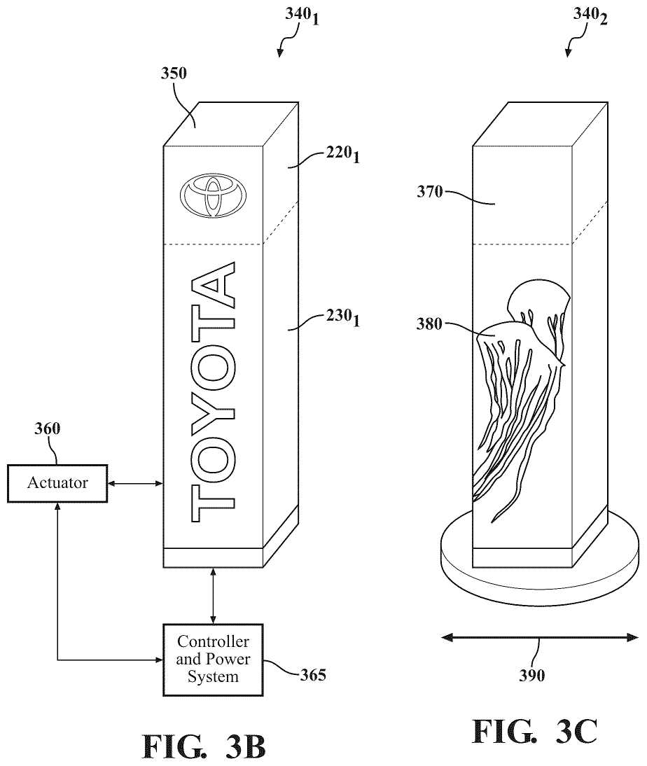

FIGS. 3A-3C illustrate embodiments and examples of the electronic system powering a display using angle-dependent imagery having integrated solar material. These configurations include systems utilizing one of battery storage for illumination and battery storage and utility power for illumination. In FIG. 3A, top portion 220₂ includes any one of the assembly 120, the assembly 122, and the assembly 124 that supplies power 320 to a light source associated with the bottom portion 230₂ that illuminates an image. For example, the top portion 220₂ and the bottom portion 230₂ can be parts of a lightbox. In one approach, the top portion 220₂ and the bottom portion 230₂ are configured with assembly 122 such that the bottom portion 230₂ comprises the viewing material 106 but without the absorption components 104. As such, the top portion 220₂ comprises mainly of the absorption components 104. In another example, the viewing material 106 on the bottom portion 230₂ is a printed graphic without the reflective components 112. In this way, the electronic system improves aesthetics while generating power from a clean power source.

In another approach, the electronic system in FIG. 3A is configured with one of the assemblies 120 and 124 such that an observer sees a continuous image from an angular range 330. For example, incident light and solar rays at angular range 310 (e.g., 90-180 degrees) perpendicular to the top portion 220₂ and the bottom portion 230₂ are transmitted toward the absorption components 104 by diffusing through the lens 102. This allows a pedestrian approaching the top portion 220₂ and the bottom portion 230₂ to see an image, whereas the absorption components 104 directly absorb solar energy at certain incident angles through unobstructed transmission. The image can communicate a message, advertising information, etc. As such, the electronic system improves aesthetics for the absorption components 104 while increasing power capture through expanding installation capabilities. In this way, the electronic system increases available installation areas of systems for energy capture by attractive designs within a community.

Regarding FIG. 3B, another embodiment where a display 340₁ is powered by one of the assemblies 120, 122, and 124 is illustrated. Furthermore, the display 340₁ may include solar cells 350 for additional energy capture when powering a light source (e.g., a backlight, a sidelight, etc.) associated with the display 340₁. Here, incident light and solar rays at angular range (e.g., 90-180 degrees) to the top portion 220₁ and the bottom portion 230₁ are transmitted toward the absorption components 104 by diffusing through the lens 102. This allows a pedestrian approaching the top portion 220₁ and the bottom portion 230₁ to see an image at a viewpoint different than the angular range. Meanwhile, the absorption components 104 directly absorbs solar energy at certain incident angles by unobstructed transmission. This improves aesthetics for the absorption components 104 while increasing power capture through expanding installation capabilities. Furthermore, the display 340₁ and assemblies may be enclosed by a flexible lenticular cover. In this way, the display 340₁ exhibits a seamless viewing image between solar capture and image sections during daylight hours and a fully illuminated and uniform image in the dark, thereby improving visual appearances.

In another configuration, as previously described, another configuration can be a vertical surface in FIG. 3B having a face for harvesting using 220₁. Meanwhile, another face illuminates the viewing material 106 on the bottom portion 230₁. As such, illumination only occurs on opposite faces, thereby allowing another design for implementation.

In one approach, the image is a single image across all lenticular angles or multiple images that give the impression of motion, depth impression with a 3D effect, etc. Here, the display 340₁ can have a first image part associated with the top portion 220₁ and a second image part associated with the bottom portion 230₁. For instance, a lenticular lens on the bottom portion 230₁ displays a visual effect for the second image part. The lenticular lens can cause an effect where the second image part transitions and moves laterally (e.g., left-to-right, right-to-left, etc.) by directing incident light. The electronic system can further enhance the visual effect through backlighting powered with energy from the absorption components 104. The second image part can also include multiple images that produce motion and a depth impression as the visual effect.

In various implementations, a controller and power system 365 draw, store, and supply power to electronic components from energy captured with the absorption components 104. Here, the controller and power system 365 can also improve energy harvesting by adapting the orientation of the display 340₁ through different seasons using actuator 360. For example, an actuator tilts the display 340₁ ten degrees toward the equator during the wintertime for capturing additional light more directly. Furthermore, motion (e.g., rotation, tilting, etc.) from the actuator 360 can cause visual effects on a displayed image through changing light transmission and reflection with the lens 102. Accordingly, the controller and power system 365 regulate power and enhance the capabilities of the display 340₁ through motion that improves energy harvesting.

Now discussing FIG. 3C, display 340₂ draws power from the absorption components 104 associated with the assembly 122 and portion 370. Here, the display 340₂ includes a lenticular lens running in a horizontal direction for a display portion having an image 380. In one approach, the display 340₂ generates motion 390 by integrating multiple images among the lenticular lens. For example, the motion 390 is a visual effect observed when passing by the display 340₂. The motion 390 may also include depth and 3D motion through the lenticular lens manipulating angles of light as a waveguide. Similarly, a lenticular lens running in a vertical direction can generate a different movement and visual effect. Another effect is illuminating the image 380 using energy captured by the absorption components 104 using various light levels. Illumination can make the motion 390 exhibit increased depth and vividness.

Moreover, the absorption components 104 can be hidden with the upper and lower portions of the display 340₂ exhibiting a similar background color. In another approach, the lenticular lens can direct light at a diagonal angle (e.g., 45 degrees) for moving the image 380 at an angle across the display 340₂ rather than horizontally. Thus, the display 340₂ can be placed anywhere without reliance on grid power for illumination, exhibit improved appearances for solar material, and exhibit high retention of energy harvesting.

Detailed embodiments are disclosed herein. However, it is to be understood that the disclosed embodiments are intended as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Furthermore, the terms and phrases used herein are not intended to be limiting but rather to provide an understandable description of possible implementations. Various embodiments are shown in FIGS. 1-3, but the embodiments are not limited to the illustrated structure or application.

The flowcharts and block diagrams in the figures illustrate the architecture, functionality, and operation of possible implementations of systems, methods, and computer program products according to various embodiments. In this regard, a block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein.

The systems, components, and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all combinations of one or more of the associated listed items. As an example, the phrase “at least one of A, B, and C” includes A, B, C, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

1. An electronic system comprising:
a first portion having a lens that directs incident light within a first angular range for absorption and a second angular range toward viewing material, the viewing material within areas of the lens and forms a first image part;
the first portion having absorption components coupled to the lens, the absorption components capture energy from the incident light within the first angular range and the absorption components being hidden and the first image part being visible at the second angular range; and
a second portion has a light source that illuminates a second image part of the viewing material using the energy, and the first image part and the second image part form a completed appearance.

2. The electronic system of claim 1 further comprising:
a lenticular lens on the second portion that displays a visual effect for the second image part, wherein the lenticular lens causes the second image part to transition laterally by directing the incident light.

3. The electronic system of claim 2, wherein the second image part includes multiple images that produce motion and a depth impression as the visual effect.

4. The electronic system of claim 1 further comprising:
reflective components near the viewing material within the areas, the reflective components directing the incident light within the second angular range towards the viewing material;
the viewing material and the reflective components are directly printed to the lens;
the absorption components are solar film that is one of a copper indium gallium diselenide (CIGS) photovoltaic (PV) film and a perovskite-based PV film; and
the solar film is flexible forming a substrate for the lens.

5. The electronic system of claim 1, wherein:
the light source illuminates the first image part;
the first portion and the second portion form a display associated with a lightbox; and
the first portion and the second portion are covered by a clear acrylic forming a shell.

6. The electronic system of claim 1, wherein:
the viewing material has a first width and transparent material near the viewing material has a second width; and
the first width and the second width comprising one of a 1:1 ratio, a 2:1 ratio, a 3:1 ratio, and a 1:3 ratio.

7. The electronic system of claim 1, wherein:
the absorption components is ethylene vinyl acetate (EVA) film that is transparent;
the EVA film is one of copper indium gallium diselenide (CIGS) photovoltaic (PV) film and a perovskite-based PV film;
the EVA film has layers that are individually encapsulated; and
the EVA film is bonded using an adhesive to reflective components near the viewing material and transparent material near the viewing material and the reflective components.

8. The electronic system of claim 1, wherein:
the lens is a lenticular film composed with one of a polymer material, a polyethylene terephthalate (PET) material, and a polystyrene (PS) material that forms a waveguide;
the lenticular film and the absorption components adapt to a structural shape; and
the lenticular film is transparent and flexible.

9. The electronic system of claim 1, wherein:
the viewing material is one of alternating and juxtaposed with the absorption components; and
the absorption components are solar ink directly printed to the lens.

10. The electronic system of claim 1, wherein:
the lens, the viewing material, the absorption components, and the second image part are flexible; and
the lens is one of a lens film and a lenticular lens that wraps and covers a body of the second portion.

11. An electronic system comprising:
a first portion having a lens that directs incident light within a first angular range toward viewing material;
a second portion having absorption components coupled to the lens, the absorption components capture energy from the incident light within a second angular range and the absorption components being hidden and the viewing material being visible at the first angular range; and
the second portion has a light source that illuminates the viewing material using the energy.

12. The electronic system of claim 11, wherein:
the lens displays a visual effect for the viewing material, wherein the lens causes the viewing material to transition laterally by directing the incident light.

13. The electronic system of claim 12, wherein the viewing material includes multiple images that produce motion and a depth impression as the visual effect.

14. The electronic system of claim 11 further comprising:
transparent material that transmits the incident light to the absorption components.

15. The electronic system of claim 11 further comprises:
reflective components adjacent to the viewing material; and
the viewing material and the reflective components are directly printed to the lens.

16. The electronic system of claim 11, wherein:
the viewing material has a first width and the absorption components near the viewing material has a second width; and
the first width and the second width comprising one of a 1:1 ratio, a 2:1 ratio, a 3:1 ratio, and a 1:3 ratio.

17. The electronic system of claim 11, wherein:
the lens is a lenticular film composed with one of a polymer material, a polyethylene terephthalate (PET) material, and a polystyrene (PS) material that forms a waveguide;
the lenticular film and the absorption components adapt to a structural shape; and
the lenticular film is transparent and flexible.

18. The electronic system of claim 11, wherein:
the lens, the viewing material, and the absorption components are flexible; and
the lens is one of a lens film and a lenticular lens that wraps and covers a body of the second portion.

19. An electronic system comprising:
a first part having a lenticular lens that directs incident light within a first angular range for absorption and a second angular range toward viewing material, the viewing material within areas of the lenticular lens and forms a first image;
the first part having absorption components coupled to the lenticular lens, the absorption components capture energy from the incident light within the first angular range and the absorption components being unviewable and the first image being viewable at the second angular range; and
a second part has a light source that illuminates a second image of the viewing material using the energy, and the first image and the second image form a completed appearance.

20. The electronic system of claim 19, wherein the lenticular lens facilitates a display of a visual effect for the second image, wherein the lenticular lens causes the second image to transition laterally by directing the incident light.
